(19) United States
(12) Patent Application Publication
(10) Pub. No.: US 2026/0372119 A1
(43) Pub. Date: Nov. 19, 2026

(54) ELECTRONIC DEVICE AND MANUFACTURING METHOD THEREOF

(71) Applicant: InnoLux Corporation, Miao-Li County (TW)

(72) Inventors: Yi-Liang CHEN, Miao-Li County (TW); Chia-Chi Ho, Miao-Li County (TW)

(73) Assignee: InnoLux Corporation, Miao-Li County (TW)

(21) Appl. No.: 19/428,283

(22) Filed: Dec. 21, 2025

Related U.S. Application Data
(60) Provisional application No. 63/747,893, filed on Jan. 22, 2025.

(30) Foreign Application Priority Data
Sep. 3, 2025 (CN) 202511248119.5

(51) Int. Cl. H10W 70/06; H10P 72/70; H10W 70/09; H10W 70/652; H10W 70/68; H10W 70/65; H10W 90/00

(52) U.S. Cl. CPC H10W 70/06; H10P 72/7412; H10P 72/744; H10W 70/09; H10W 70/6528; H10W 70/681; H10W 70/6565; H10W 90/7295

(57) ABSTRACT

An electronic device and a manufacturing method thereof are provided. The manufacturing method includes providing a carrier; forming a release layer on the carrier; providing a device structure on the release layer and exposing a portion of an upper surface of the release layer; forming a barrier structure on the portion of the upper surface of the release layer; and performing a surface treatment step on the device structure after the barrier structure is formed.

### CROSS REFERENCE TO RELATED APPLICATION

This application claims the benefit of U.S. Provisional Application No. 63/747,893, filed on Jan. 22nd, 2025. The content of the application is incorporated herein by reference.

### BACKGROUND OF THE DISCLOSURE

### 1. Field of the Disclosure

The present disclosure relates to an electronic device and a manufacturing method thereof and particularly to an electronic device including a device structure and a manufacturing method thereof.

### 2. Description of the Prior Art

With advancement of technology, packaging techniques have been developed to form a redistribution layer (RDL) on a device structure. During packaging process, the device structure is positioned on a release layer and a carrier to reduce warpage of the device structure. However, the area of the release layer is typically greater than that of the device structure. As a result, during the formation of the redistribution layer on the device structure, portion of the release layer remains exposed. This exposure allows physical or chemical etching or cleaning processes to infiltrate the release layer during the formation of the redistribution layer, leading to insufficient adhesion. Consequently, the device structure is prone to delamination from the carrier during manufacturing processes.

### SUMMARY OF THE DISCLOSURE

An objective of the present disclosure is to provide an electronic device including a device structure and a manufacturing method thereof to reduce delamination of the device structure from a carrier.

According an embodiment of the present disclosure, a manufacturing method of an electronic device is provided and includes providing a carrier; forming a release layer on the carrier; providing a device structure on the release layer and exposing a portion of an upper surface of the release layer; forming a barrier structure on the portion of the upper surface of the release layer; and performing a surface treatment step on the device structure after forming the barrier structure.

According an embodiment of the present disclosure, an electronic device is provided and includes an electronic unit, a package layer, and a circuit structure. The package layer surrounds the electronic unit. The circuit structure is disposed on the electronic unit and the package layer and electrically connected to the electronic unit, wherein the circuit structure includes at least one pad, a side surface of the at least one pad has a recess in a cross-sectional view.

In the manufacturing method of the electronic device of the present disclosure, before performing the surface treatment step, the exposed portion of the release layer may be shielded by the barrier structure, thereby reducing the degree of penetration into the release layer during the surface treatment step. This prevents a reduction in adhesion of the release layer and lowers the probability of the device structure delaminated from the carrier during subsequent processes.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a top view schematic diagram illustrating one of steps in a manufacturing method of an electronic device according to a first embodiment of the present disclosure.

FIG. 2 is a cross-sectional schematic diagram taken along a cross-sectional line A–A′ of FIG. 1.

FIG. 3 is a cross-sectional schematic diagram of the electronic device according to the first embodiment of the present disclosure.

FIG. 4 is a top view schematic diagram illustrating one of steps in a manufacturing method of an electronic device according to a second embodiment of the present disclosure.

FIG. 5 is a top view schematic diagram illustrating one of steps in a manufacturing method of an electronic device according to a third embodiment of the present disclosure.

FIG. 6 is a top view schematic diagram illustrating one of steps in a manufacturing method of an electronic device according to a fourth embodiment of the present disclosure.

FIG. 7 is a top view schematic diagram illustrating one of steps in a manufacturing method of an electronic device according to a fifth embodiment of the present disclosure.

FIG. 8 is a top view schematic diagram illustrating one of steps in a manufacturing method of an electronic device according to a sixth embodiment of the present disclosure.

FIG. 9 is a cross-sectional schematic diagram taken along a cross-sectional line B–B′ of FIG. 8.

FIG. 10 is a top view schematic diagram illustrating one of steps in a manufacturing method of an electronic device according to a seventh embodiment of the present disclosure.

### DETAILED DESCRIPTION

The contents of the present disclosure will be described in detail with reference to specific embodiments and drawings. It is noted that, for purposes of illustrative clarity and ease of understanding by the readers, the following drawings in the present disclosure may be a simplified illustrations, and elements therein may not be drawn to scale. The numbers and sizes of the elements in the drawings are merely illustrative and are not intended to limit the scope of the present disclosure.

Certain terms are used throughout the specification and the appended claims of the present disclosure to refer to specific elements. Those skilled in the art should understand that electronic equipment manufacturers may refer to an element by different names, and this document does not intend to distinguish between elements that differ in name but not in function. In the following specification and claims, the terms “comprise”, “include” and “have” are open-ended fashion, so they should be interpreted as “including but not limited to…”.

The ordinal numbers used in the specification and the appended claims, such as “first”, “second”, etc., are used to describe the elements of the claims. This does not mean that the element has any previous ordinal numbers, nor does this represent the order of a certain element and another element, or the sequence in a manufacturing method. These ordinal numbers are merely used to make a claimed element with a certain name be clearly distinguishable from another claimed element with the same name.

In addition, when one element or layer is “connected to” another element or layer, it may be understood that the element or layer is directly connected to the another element or layer physically or electrically, and alternatively, the two may be physically or electrically connected through other element or layer (indirectly). On the contrary, when the element or layer is “directly connected to” another element or layer, it may be understood that there is no other element or layer between the two for physical or electrical connection. The term “connect” may include means of “directly connect” or “indirectly connect”. Besides, the term “electrically connect” or “couple” includes any direct or indirect means of electrical connection.

In the present disclosure, when one element is “disposed on” another element, the manufacturing procedure or sequence of forming the element and the another element is not limited thereto. In the present disclosure, when one element is “disposed on” another element, it may include one element is disposed on a side wall of another element.

As disclosed herein, the terms “approximately”, “essentially”, “about”, or “substantially” generally mean within 20%, 10%, 5%, 3%, 2%, 1%, or 0.5% of the reported numerical value or range. The numbers given herein are approximated numbers, and that is, without specifically describing with the terms “approximately”, “essentially”, “about”, or “substantially”, it may still imply the meaning of the terms “approximately”, “essentially”, “about”, or “substantially”.

The term “between a number A and a number B” is interpreted as including the number A and the number B or as including at least one of the number A and the number B, and as including other numbers between the number A and the number B.

In the present disclosure, the depth, thickness, length, width, height, distance, and aperture may be measured by using an optical microscope (OM), a scanning electron microscope (SEM) or other approaches, but not limited thereto.

In the present disclosure, the definition of roughness may be a peak-to-valley distance of 0.15 μm to 1 μm of surface undulations observed by a SEM. The measurement of determining the roughness may include using a SEM or a transmission electron microscope (TEM), etc. to observe peaks and valleys of surface undulations in a proper magnified ratio, and comparing the surface undulations by taking a unit length (e.g., 10 μm) to obtain its roughness range. Here, the term “proper magnified ratio” means at least one surface may be observed a roughness (Rz) or an averaged roughness (Ra) with at least 10 peaks in the visual field in this magnified ratio.

It should be understood that, according to the following embodiments, features of different embodiments may be replaced, recombined or mixed to constitute other embodiments without departing from the spirit of the present disclosure. The features of various embodiments may be mixed arbitrarily and used in different embodiments without departing from or conflicting with the spirit of the present disclosure.

Unless otherwise defined, all terms (including technical and scientific terms) used herein have the same meaning as commonly understood by those skilled in the art. It should be understood that these terms, such as those defined in commonly used dictionaries, should be interpreted as having meaning consistent with the relevant technology and the background or context of the present disclosure, and should not be interpreted in an idealized or excessively formal way, unless there is a specific definition in the embodiments of the present disclosure.

An electronic device of the present disclosure may, for example, include a display device, a light emitting device, a sensing device, an antenna device, a touch device, a tiled device, a package device, or other suitable electronic devices, but not limited thereto. The electronic device may, for example, be a bendable, stretchable, foldable, rollable, and/or flexible electronic device, but not limited thereto. The sensing device may, for example, be a sensing device used for detecting variation in capacitances, light, heat, or ultrasound, but not limited thereto. The sensing device may, for example, include a bio-sensor, a touch sensor, a fingerprint sensor, other suitable sensors, or any combination of the aforementioned sensors. The antenna device may include liquid crystal antenna, varactor diode antenna, or antennas of other types, but not limited thereto. The tiled device may, for example, include a tiled display device or a tiled antenna device, but not limited thereto. Furthermore, the appearance of the electronic device may be, for example, rectangular, circular, polygonal, a shape with curved edges, curved or other suitable shapes. The electronic device may have peripheral systems, such as a driving system, a control system, a light source system, a shelf system, etc. The electronic device may include electronic units, in which the electronic units may include a passive element and an active element, and for example, include a capacitor, a resistor, an inductor, a diode, a transistor, a sensor, etc. It is noted that the electronic device of the present disclosure may be any combination of the above-mentioned devices, but not limited thereto. The manufacturing method of the package device of the present disclosure may, for example, be applied to a wafer-level package (WLP) process or a panel-level package (PLP) process, wherein the WLP or the PLP may include a chip-first process or a chip-last process, but not limited thereto. The electronic device may include data center, high-speed computing system, high bandwidth memory (HBM) package, system on a chip (SoC), system in a package (SiP), antenna in package (AiP), co-packaged optics (CPO), or any combination of the aforementioned devices, but not limited thereto.

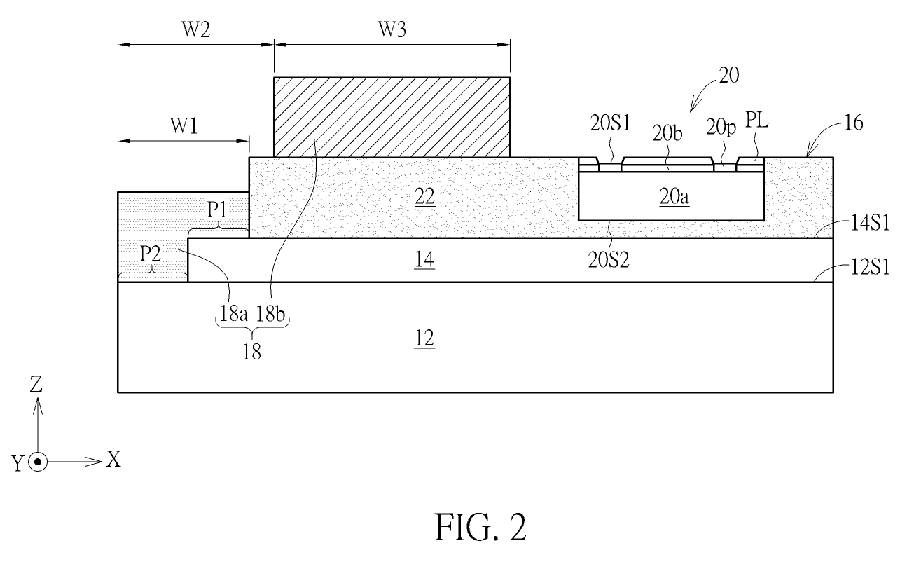

The following figures show a direction X, a direction Y, and a direction Z. The direction Z may be a normal direction or a top view direction of the electronic device, and as shown in FIG. 2, the direction Z may be perpendicular to a first surface 12S1 of a carrier 12. The direction X and the direction Y each may be a horizontal direction and may be perpendicular to the direction Z. As shown in FIG. 2, the direction X and the direction Y may be parallel to the first surface 12S1 of the carrier 12, and the direction X and the direction Y may be perpendicular to each other. The following contents may describe the spatial relations of structures based on the direction X, the direction Y, and the direction Z in the following figures.

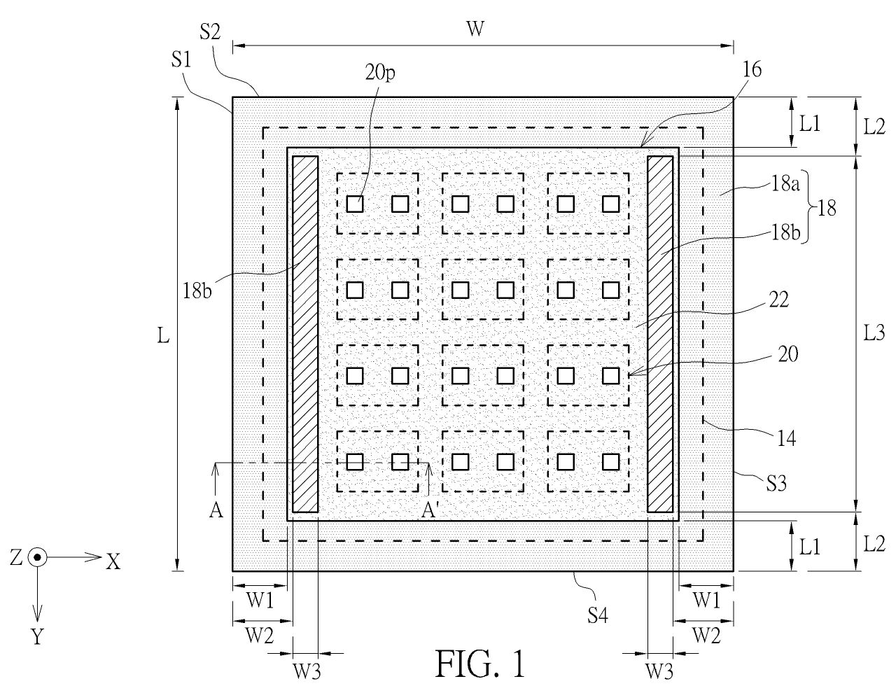

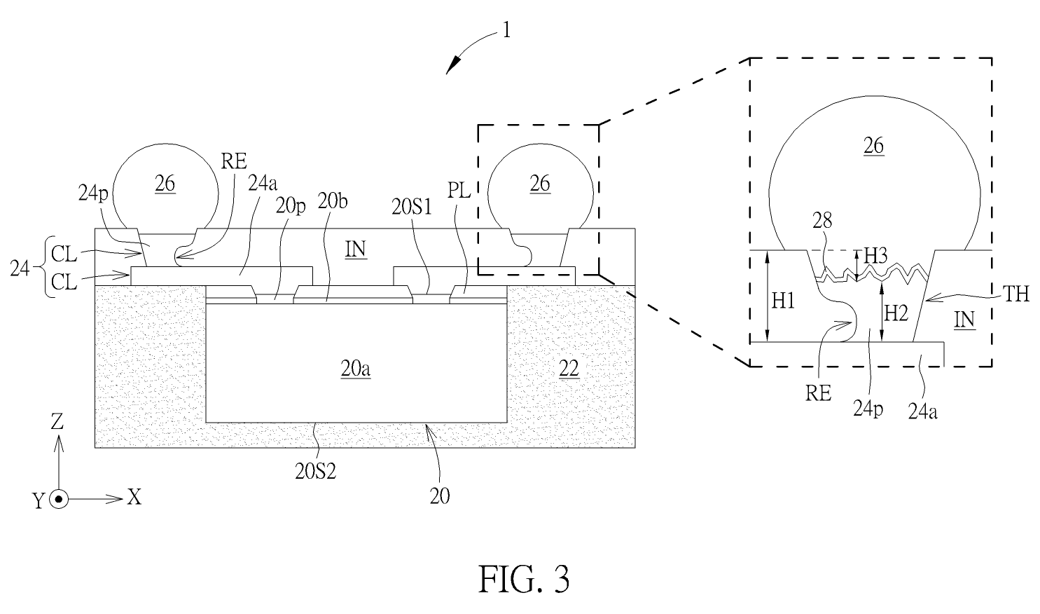

Refer to FIGS. 1-3. FIG. 1 is a top view schematic diagram illustrating one of steps in a manufacturing method of an electronic device according to a first embodiment of the present disclosure. FIG. 2 is a cross-sectional schematic diagram taken along a cross-sectional line A–A′ of FIG. 1. FIG. 3 is a cross-sectional schematic diagram of the electronic device according to the first embodiment of the present disclosure. The manufacturing method of the electronic device 1 may include at least the following steps: providing a carrier 12; forming a release layer 14 on the carrier 12; providing a device structure 16 on the release layer 14, thereby exposing a portion P1 of the upper surface 14S1 of the release layer 14; forming a barrier structure 18 on the carrier 12 and the portion P1 of the upper surface 14S1 of the release layer 14; and performing a surface treatment step on the device structure 16 after the barrier structure 18 is formed. It is should be noted that, through the above-mentioned manufacturing method, the exposed portion of the release layer 14 may be shielded by the barrier structure 18 before performing the surface treatment step, such that the degree of damage to the release layer 14 during the surface treatment step may be reduced to prevent adhesion of the release layer 14 from being decreased, thereby lowering the risk of the device structure 16 delaminated from the carrier 12 in subsequent processes. The manufacturing method of the present disclosure is not limited to the steps described above and may include other steps before, after, or during any of the above-mentioned steps.

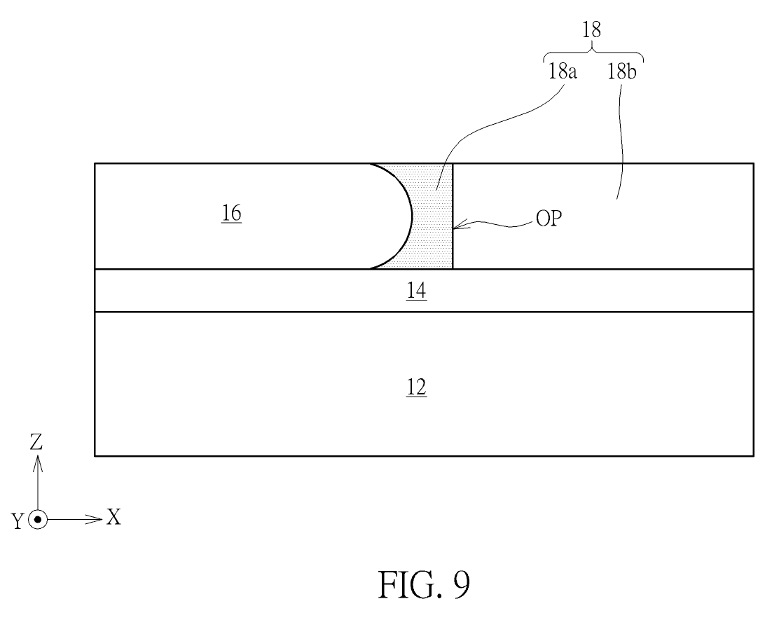

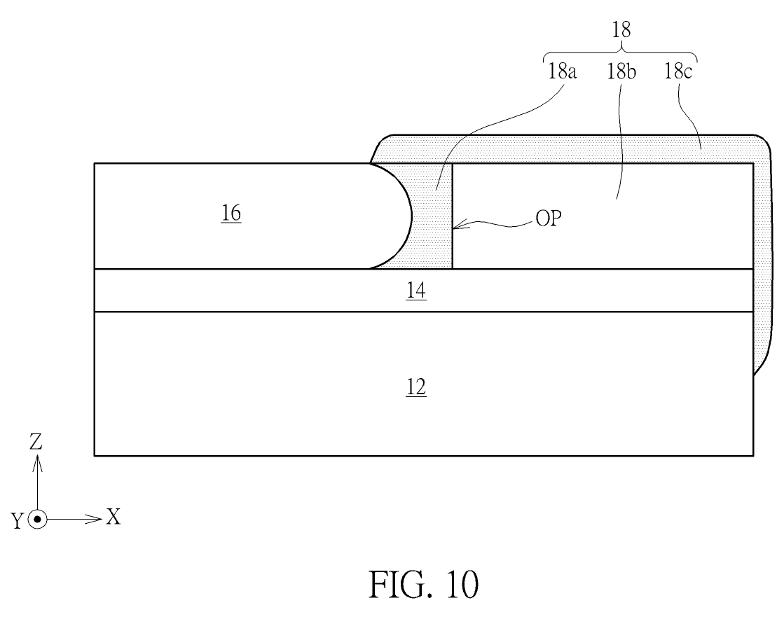

The manufacturing method of the electronic device 1 of this embodiment is further described below with reference to FIGS. 1-3. As shown in FIGS. 1 and 2, the carrier 12 may first be provided, wherein the carrier 12 may be used to support the device structure 16. The carrier 12 may include, for example, a steel plate, a transparent glass substrate, a silicon substrate, or other suitable substrates. Subsequently, the release layer 14 is formed on the carrier 12. The release layer 14 has adhesive property before being detached and may be directly disposed on the carrier 12. The release layer 14 may be used to temporarily fix the device structure 16 onto the carrier 12 during subsequent processes and facilitate the separation of the device structure 16 from the carrier 12. In this embodiment, the release layer 14 may not cover the upper surface 12S1 of the carrier 12, thereby exposing a portion P2 of the upper surface 12S1, but not limited thereto. In some embodiments, the release layer 14 may cover the entire upper surface 12S1 of the carrier 12, as shown in FIGS. 9 or 10.

In some embodiments, an anti-warping layer (not shown) may optionally be formed on the carrier 12 before forming the release layer 14, in order to reduce warpage generated during subsequent processes and improve process yield. The anti-warping layer may include, for example, silicon oxide, silicon nitride, silicon oxynitride, tetrathoxysilane (TEOS), or other suitable materials.

As shown in FIGS. 1 and 2, the device structure 16 is subsequently provided on the release layer 14, and is fixed to the carrier 12 through the release layer 14. The device structure 16 of this embodiment may be, for example, a package structure including at least one electronic unit 20 and a package layer 22, wherein the package layer 22 at least surrounds the electronic unit 20 and exposes a portion P1 of the upper surface 14S1 of the release layer 14. In FIG. 1, multiple electronic units 20 are illustrated as an example, but not limited thereto. In the embodiment shown in FIG. 2, the device structure 16 may first be formed on another carrier, and then flipped upside down and disposed on the release layer 14. The method for forming the device structure 16 may include disposing the electronic unit 20 on the another carrier with its active surface facing the another carrier, and forming the package layer 22 on the another carrier and the electronic unit 20. In this case, when the device structure 16 is disposed on the release layer 14, a portion of the package layer 22 may be located between the electronic unit 20 and the release layer 14, but not limited thereto. In some embodiments, the package layer 22 on the electronic unit 20 may be removed before disposing the device structure 16 on the release layer 14. In such case, the electronic unit 20 may, for example, be in direct contact with the release layer 14. The package layer 22 may be formed by a molding process or other suitable processes. The package layer 22 may include, for example, an epoxy molding compound (EMC) or other suitable packaging materials.

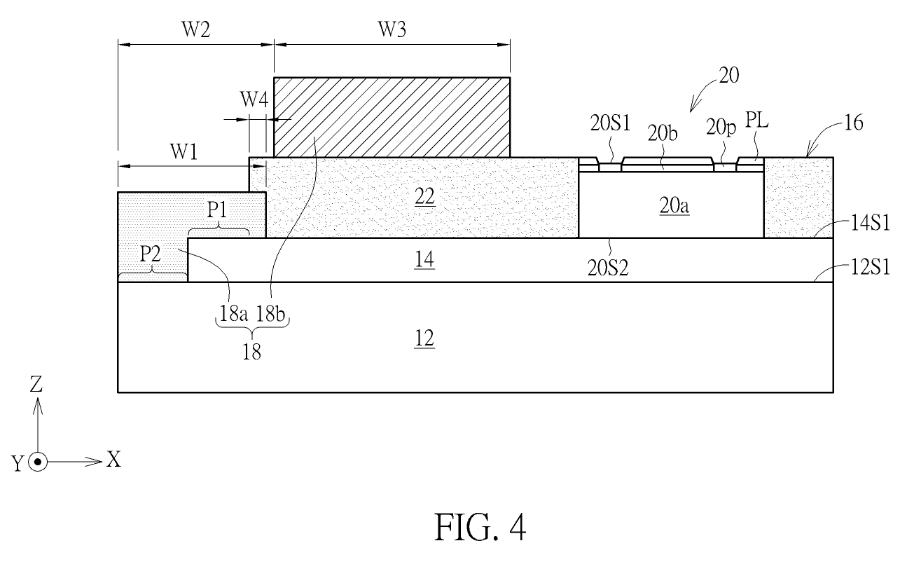

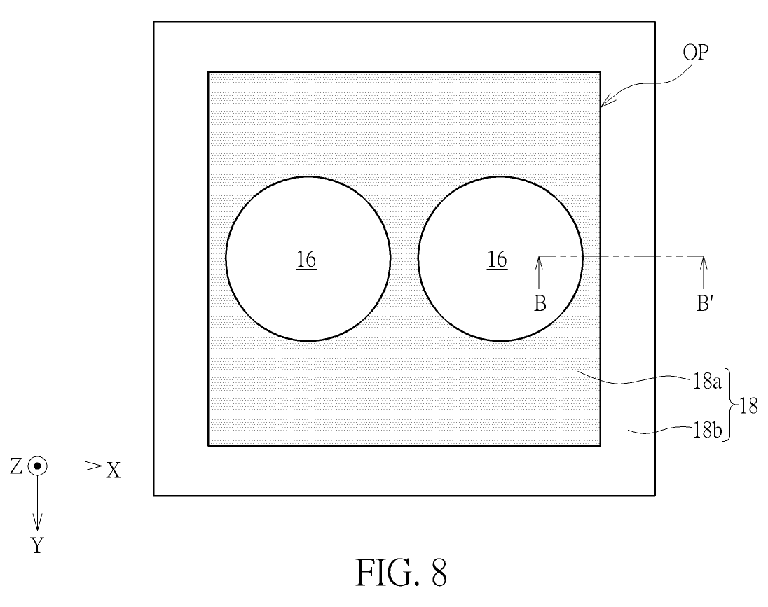

In the present disclosure, the step of providing the device structure 16 is not limited to the aforementioned method. According to some embodiments, as shown in FIG. 4, the step of providing the device structure 16 may alternatively include disposing the electronic units 20 on the release layer 14 with its surface 20S1 facing upward, and forming the package layer 22 on the electronic unit 20, wherein the package layer 22 at least surrounds the electronic unit 20. In this case, the step of forming the package layer 22 may include, for example, forming a packaging material between and over the electronic units 20, and then removing the packaging material on the electronic units 20 by a grinding process or other suitable processes to expose the electronic units 20, but not limited thereto. In some embodiments, the device structure 16 may not be limited to the package structure, but may alternatively be other suitable structures including the electronic units 20, such as a wafer, as shown in FIGS. 8-10.

The electronic unit 20 may include a chip, a chip package structure, a chip assembly structure, or other types of device structures. As shown in FIG. 2, the electronic unit 20 may include, for example, a body portion 20a, an insulating layer 20b, and a plurality of pads 20p, wherein the insulating layer 20b and the pads 20p are disposed on the same side of the body portion 20a. The insulating layer 20bmay have a plurality of openings respectively exposing the corresponding pads 20p. The electronic unit 20 may have a surface 20S1 and a surface 20S2 opposite to each other. The surface of the electronic unit 20 having the pads 20p may be referred to as the surface 20S1; that is, surfaces of the pads 20p are parts of the surface 20S1, and the surface of the electronic unit 20 opposite to surface 20S1 is the surface 20S2. For example, the surface 20S1 may be an active surface, and the surface 20S2 may be a back surface. It should be understood that the pads 20pmay serve as signal input/output (I/O) pads of the electronic unit 20, and may include, for example, aluminum, nickel, gold, copper, nitrides, or other suitable conductive materials. In the embodiment of FIG. 2, the electronic unit 20 may further include a protection layer PL disposed on the insulating layer 20b. The protection layer PL may further have openings exposing the pads 20p, but not limited thereto. According to some embodiments, when the electronic unit 20 is disposed on the release layer 14 with the surface 20S1 facing upward, the openings of the protection layer PL may be formed after the package layer 22 on the electronic unit 20 is removed.

As shown in FIG. 2, after the device structure 16 is formed or disposed, the barrier structure 18 may be formed on a portion P1 of the upper surface 14S1 of the release layer 14 and a portion P2 of the upper surface 12S1 of the carrier 12. In one embodiment, the barrier structure 18 may include a first portion 18aand a second portion 18b. After forming the package layer 22 (or after providing the package structure 16), the first portion 18a may be formed on the portion P1 of the upper surface 14S1 of the release layer 14 and extend onto the portion P2 of the upper surface 12S1 of the carrier 12, such that the first portion 18a extends onto the carrier 12 and covers a side surface of the release layer 14. The second portion 18bmay be formed on the package layer 22 of the device structure 16. Hence, the first portion 18aand the second portion 18b may protect the exposed release layer 14, thereby reducing risk of the package structure 16 delaminated from the release layer 14 during subsequent processes. For example, the chemical resistances and/or moisture absorptions of the first portion 18aand the second portion 18b may be greater than that of the release layer 14. According to some embodiments, a width of the portion P2 of the upper surface 12S1 of the carrier 12 may be greater than or equal to 1 millimeter (mm).

When the first portion 18a and the second portion 18b include different materials, the first portion 18a may be formed either before or after forming the second portion 18b. In other words, the first portion 18aand the second portion 18b may be formed of different barrier layers. The first portion 18amay include an insulating material, and the second portion 18b may include a conductive material, such as conductive adhesive, copper, or other suitable metals. The insulating material of the first portion 18amay include, for example, silicon oxide, silicon nitride, or other suitable insulating materials. In some embodiments, the first portion 18aand the second portion 18b may alternatively be formed of the same material, such as a conductive material, or formed of the same barrier layer.

As shown in FIG. 1, the carrier 12 has a width W in the direction X and a length L in the direction Y. In a top view of the barrier structure 18, the first portion 18a may surround the package layer 22, in which parts of the first portion 18a respectively located on left and right sides of the package layer 22 may each have a width W1 in the direction X, and parts of the first portion 18a located on the upper and lower sides of the package layer 22 may each have a length L1 in the Y direction. Furthermore, the width W, the width W1, the length L, and the length L1 may satisfy the following relationship: 0.5≤((W-2×W1)×(L-2×L1))/(W×L)≤0.9. Accordingly, the first portion 18asufficiently shields the release layer 14, thereby enhancing the durability of the release layer 14 during the manufacturing process.

According to some embodiments, in a top view, a distance W2 may be present between the second portion 18badjacent to the edge S1 of the carrier 12 and the edge S1, and the distance W2 may be present between the second portion 18badjacent to the edge S3 of the carrier 12 and the edge S3. Additionally, a distance L2 may exist between the second portion 18band the edge S2 of the carrier 12 and between the second portion 18b and the edge S4 of the carrier 12. Furthermore, the width W, the distance W2, the length L, and distance L2 may optionally satisfy the following relationship: 0.5≤((W-2×W2)×(L-2×L2))/(W×L)≤0.8, so as to enhance the durability of the release layer 14 during the manufacturing process. In some embodiments, the second portion 18bmay have a width W3 in the X direction and a length L3 in the Y direction. The width W, the width W3, the length L, and the length L3 may optionally satisfy the following relationship: 0.01≤(W3×L3×n)/(W×L)≤0.3, so as to improve the durability of the release layer 14 during the manufacturing process, where n represents the number of second portions 18b.

After the barrier structure 18 is formed, the surface treatment step may be performed on the device structure 16. As shown in FIG. 3, the manufacturing method of this embodiment may further include forming a circuit structure 24 on the package layer 22 and the protection layer PL of the electronic unit 20 after the barrier structure 18 is formed. The surface treatment step may include, for example, laser etching, dry etching, wet etching, plasma treatment, photoresist development, transfer printing, cleaning, roughening processes, combinations thereof, or other suitable processes. These processes may be performed before, after, or during the step of forming the circuit structure 24.

The circuit structure 24 may include, for example, at least one conductive layer CL and at least one insulating layer IN, which allow for signal line redistribution and/or further expansion of line fan-out area. Alternatively, different electronic units 20 may be electrically connected to each other through the circuit structure 24. Or, the circuit structure 24 may serve as a substrate used as an electrical interface routing between one circuit and another circuit. A purpose of the circuit structure is to expand wirings to have greater distance between the wirings or to redistribute the wirings to other wirings with different distances. In other words, the circuit structure 28 in the present disclosure may be a redistribution layer/structure.

In FIG. 3, the number of conductive layers CL is exemplified as two, and the number of insulating layers IN is exemplified as one, but not limited thereto. In other words, after the openings are formed in the protection layer PL, the conductive layer CL, the insulating layer IN, and another conductive layer CL may be sequentially formed on the package layer 22 and the electronic unit 20. The insulating layer IN may be formed by deposition, surface treatment, or other processes. The method of forming the conductive layer CL may include electroplating, surface treatment, or other processes. It should be noted that the second portion 18bmay serve as an electrode for the electroplating process, so that the second portion 18b having the sufficient length L3 may help improve electroplating efficiency. According to some embodiments, the surface treatment step may be performed before forming the circuit structure 24 on the package layer 22 to roughen the surface of the package layer 22. Alternatively, during the process of alternately stacking the conductive layers CL and the insulating layers IN, the surface treatment step may be performed to roughen the surfaces of the conductive layers CL and/or the insulating layers IN.

For example, the insulating layer IN may include polyimide (PI), photosensitive polyimide (PSPI), Ajinomoto build-up film (ABF), silicon oxide (SiOx), silicon nitride (SiNx), silicon oxynitride (SiOxNy), or other suitable dielectric materials. The conductive layer CL may include conductive materials such as copper (Cu), titanium (Ti), aluminum (Al), molybdenum (Mo), nickel (Ni), ruthenium (Ru), tantalum (Ta), tungsten (W), nitrides, carbides, or other conductive materials, or any combination thereof, but is not limited thereto.

In the embodiment shown in FIG. 3, the conductive layer CL adjacent to the electronic unit 20 may include a plurality of traces 24a, and the traces 24a may extend into the corresponding openings of the protection layer PL to be electrically connected to the corresponding pads 20p, respectively. The insulating layer IN may have at least one through hole TH that exposes a corresponding trace 24a, and the conductive layer CL farthest from the electronic unit 20 (i.e., the uppermost conductive layer CL) may include at least one pad 24pdisposed in the corresponding through hole TH to be electrically connected to the corresponding trace 24a. As shown in an enlarged view on the right side of FIG. 3, a depth H1 of the through hole TH may be greater than a thickness H2 of the pad 24p, for example. In some embodiments, a distance H3 between a level of an upper surface of the pad 24p and a level of an upper surface of the insulating layer IN may, for example, range from 1 μm to 10 μm.

After the step of forming the circuit structure 24 (or the surface treatment step), the release layer 14, the barrier structure 18, and the carrier 12 may be removed. The method of removing the release layer 14 may include photonic debonding (i.e., irradiating the release layer 14 with light), thermal debonding (i.e., heating the release layer 14), other suitable methods, or any combination thereof. For example, depending on the debonding method, the release layer 14 may be used with different types of carriers. As an example, a photonic debonding-type release layer 14 may be used with a transparent glass substrate, while a thermal debonding-type release layer 14 may be used with a steel plate. The release layer 14 may include, for example, a UV-release film, a heat-release tape (HRT), other suitable materials, or any combination thereof.

The method of removing the first portion 18a of the barrier structure 18 may include irradiating the first portion 18a of the barrier structure 18 with light or other suitable methods. For instance, when the release layer 14 is removed by heating, the light used to irradiate the first portion 18a of the barrier structure 18 may include ultraviolet light or other suitable light. Alternatively, when the release layer 14 is removed by light irradiation, the wavelength range of the light used to irradiate the first portion 18a of the barrier structure 18 may not be overlapped with the wavelength range used for the release layer 14.

After removing the release layer 14, connection elements 26 may be formed on the pads 24p, such that the device structure 16 may be bonded to other component or substrate through the connection elements 26. Accordingly, the electronic device 1 of this embodiment may be formed. The connection elements 26 may include, for example, solder balls, nickel, gold, copper, gallium, or other suitable conductive materials. It should be noted that the upper surface of the pad 24p may have a rough surface, which enhances the bonding strength between the connection element 26 and the pad 24p. According to some embodiments, the step of forming the connection elements 26 may alternatively be performed before removing the release layer 14, the barrier structure 18, and the carrier 12. In some embodiments, a singulation process may optionally be performed between the step of forming the circuit structure 24 and the step of forming the connection elements 26, or after the step of forming the connection elements 26. The singulation process may include, for example, laser cutting, blade cutting, or other suitable cutting processes.

In the embodiment of FIG. 3, during the step of forming the connection elements 26, an intermetallic compound (IMC) 28 may be formed between the connection element 26 and the pad 24p to enhance the bonding strength, but not limited thereto.

As shown in FIG. 3, the electronic device 1 may include at least one electronic unit 20, a package layer 22, and a circuit structure 24, wherein the package layer 22 may surround the electronic unit 20, and the circuit structure 24 may be disposed on the electronic unit 20 and the package layer 22 and be electrically connected to the electronic unit 20. The circuit structure 24 may include at least one pad 24p, and in a cross-sectional view, a side surface of the pad 24pmay have, for example, a C-shaped recess RE. In other words, a width of a portion of the pad 24padjacent to the upper surface of the insulating layer IN in the X direction may be greater than a width of another portion of the pad 24p farther from the upper surface of the insulating layer IN in the X direction, thereby increasing contact area between the pad 24p and the connection element 26 and enhancing the bonding strength.

The electronic device and the manufacturing method thereof are not limited to the above-mentioned embodiments and may have other embodiments. To simplify description, different embodiments in the following contents will use the same notations to the same elements as the first embodiment. To clearly illustrate different embodiments, differences between different embodiments will be described below, and repeated parts will not be detailed redundantly.

FIG. 4 is a top view schematic diagram illustrating one of steps in a manufacturing method of an electronic device according to a second embodiment of the present disclosure. As shown in FIG. 4, the manufacturing method of this embodiment differs from the embodiment shown in FIG. 2 in that the first portion 18a of the barrier structure 18 may be formed on the portion P1 of the upper surface 14S1 of the release layer 14 and the portion P2 of the upper surface 12S1 of the carrier 12 before the step of forming the package layer 22 or providing the electronic unit 20. Specifically, the step of providing the device structure 16 may include disposing the electronic unit 20 on the release layer 14 with its surface 20S1 facing upward, and forming the package layer 22 on the electronic unit 20. In this case, the first portion 18aand the second portion 18b may be formed of different layers, wherein the first portion 18a may be formed before the step of forming the package layer 22 or the step of providing the electronic unit 20, and the second portion 18b may be formed after the package layer 22 is formed, but not limited thereto. In some embodiments, when the barrier structure 18 includes only the first portion 18a, the barrier structure 18 may be formed on the portions P1 and P2 before providing the device structure 16. Alternatively, when the barrier structure 18 includes only the first portion 18a, the barrier structure 18 may be formed on the portions P1 and P2 between the steps of providing the electronic unit 20 and forming the package layer 22. In some embodiments, the step of providing the device structure 16 in FIG. 4 may adopt the method of the embodiment shown in FIG. 2. In this case, the first portion 18ais formed before the step of providing the device structure 16.

In the embodiment of FIG. 4, the part of the first portion 18a located on the upper surface 14S1 may be, for example, wider than the portion P1, such that a portion of the package layer 22 subsequently formed may be located on the first portion 18a. For example, in a cross-sectional view, a width W4 of a portion of the package layer 22 overlapped with the first portion 18a viewed along the direction Z may be less than 1 millimeter, but not limited thereto. Other parts of the manufacturing method shown in FIG. 4 are the same as those in the previous embodiments, so that the reference may be made in the aforementioned contents and will not be repeated here.

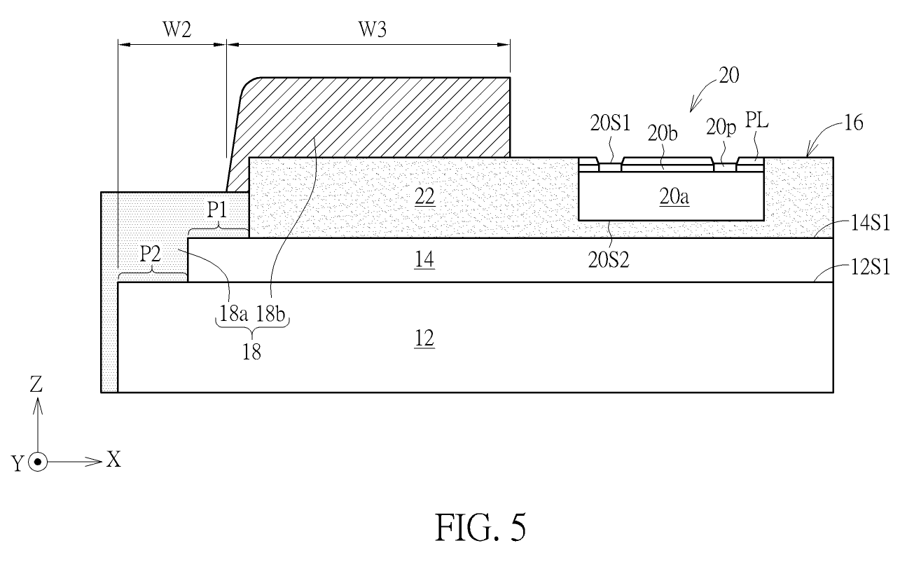

FIG. 5 is a top view schematic diagram illustrating one of steps in a manufacturing method of an electronic device according to a third embodiment of the present disclosure. As shown in FIG. 5, the manufacturing method of this embodiment differs from the embodiment shown in FIG. 2 in that the first portion 18a of the barrier structure 18 may extend onto the side surface of the carrier 12, so that solution or gas penetrating through the gap between the first portion 18a and the carrier 12 and reaching the release layer 14 during the processes may be reduced, thereby decreasing the risk of the package structure 16 delaminated from the carrier 12 in subsequent processes. In this embodiment, the second portion 18b of the barrier structure 18 may optionally extend onto the first portion 18a, for example, in direct contact with the first portion 18a, such that the second portion 18b may be used to reduce the risk of the solution or gas penetrating through the gap between the first portion 18a and the package layer 22 and reaching the release layer 14, thereby reducing the probability of delamination of the package structure 16. According to some embodiments, the configuration in FIG. 5 where the first portion 18a extends onto the side surface of the carrier 12 may be applicable to any of the embodiments described above or below. Similarly, the configuration in FIG. 5 where the second portion 18b extends onto the first portion 18a may be applicable to any of the embodiments described above or below.

In some embodiments, when the first portion 18a extends onto the side surface of the carrier 12, the barrier structure 18 in FIG. 5 may optionally not include the second portion 18b. In other embodiments, when the second portion 18b extends onto the first portion 18a, the first portion 18a in FIG. 5 may not extend to the side surface of the carrier 12. Other parts of the manufacturing method shown in FIG. 5 are the same as those described in the aforementioned embodiments, so that the reference may be made in the aforementioned contents and will not be repeated here.

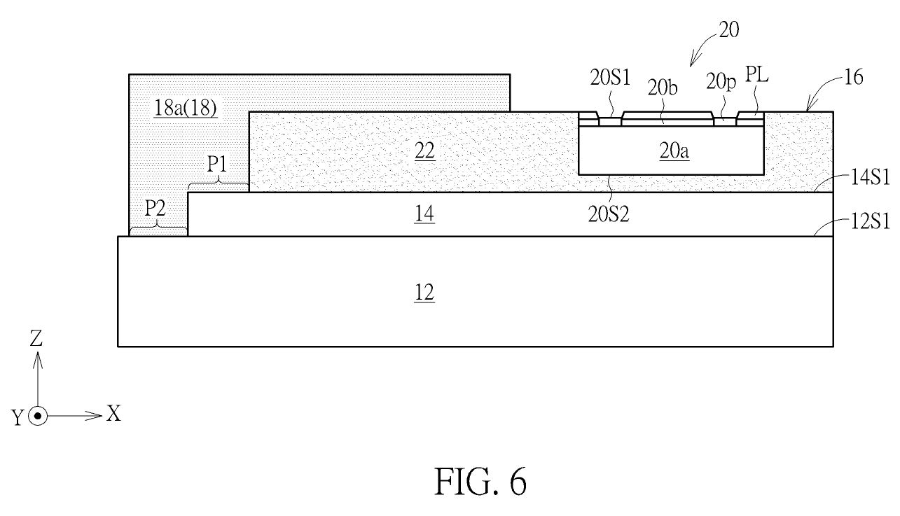

FIG. 6 is a top view schematic diagram illustrating one of steps in a manufacturing method of an electronic device according to a fourth embodiment of the present disclosure. As shown in FIG. 6, the manufacturing method of this embodiment differs from the embodiment shown in FIG. 2 in that the first portion 18a of the barrier structure 18 may further extend onto the upper surface of the package layer 22 of the device structure 16. In this embodiment, the barrier structure 18 may optionally not include the second portion 18bshown in FIG. 2. In such case, the barrier structure 18 may include conductive adhesive or other conductive materials. In other words, the barrier structure 18 in FIG. 6 may not only protect the release layer 14 but also serve as an electrode for the electroplating process, but not limited thereto. Other parts of the manufacturing method shown in FIG. 6 are the same as those described in the aforementioned embodiments, so that the reference may be made in the aforementioned contents and will not be repeated here.

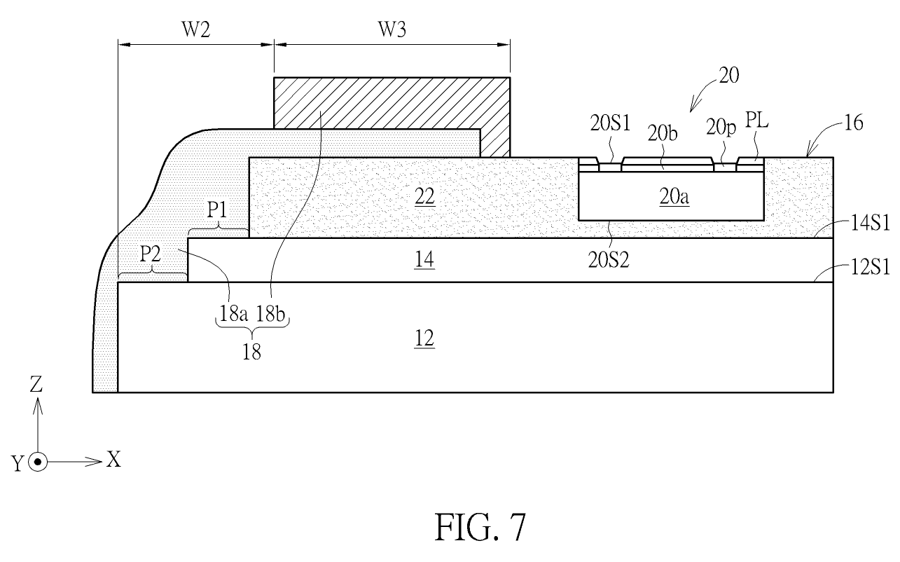

FIG. 7 is a top view schematic diagram illustrating one of steps in a manufacturing method of an electronic device according to a fifth embodiment of the present disclosure. As shown in FIG. 7, the manufacturing method of this embodiment differs from the embodiment shown in FIG. 2 in that the first portion 18a of the barrier structure 18 may further extend onto the side surface of the carrier 12. In the embodiment of FIG. 7, the first portion 18a may include, for example, conductive adhesive or other suitable adhesive materials. According to some embodiments, when the first portion 18a includes conductive adhesive, the barrier structure 18 may optionally not include the second portion 18b. Other parts of the manufacturing method shown in FIG. 7 are the same as those described in the aforementioned embodiments, so that the reference may be made in the aforementioned contents and will not be repeated here.

FIG. 8 is a top view schematic diagram illustrating one of steps in a manufacturing method of an electronic device according to a sixth embodiment of the present disclosure, and FIG. 9 is a cross-sectional schematic diagram taken along a cross-sectional line B–B′ of FIG. 8. As shown in FIGS. 8 and 9, the manufacturing method of this embodiment differs from the embodiment shown in FIG. 2 in that the device structure 16 includes a wafer, wherein the wafer may include a plurality of electronic units. In this case, the second portion 18b of the barrier structure 18 may include, for example, a fixture having an opening OP in the top view, which is used to define an area for disposing the device structure 16. In other words, at least one device structure 16 may be disposed in the opening OP. In the manufacturing method of this embodiment, the second portion 18b may be formed on the release layer 14 before providing the device structure 16, and after the device structure 16 is provided, the first portion 18a may be formed between the device structure 16 and the second portion 18b. The first portion 18amay include, for example, adhesive material, conductive material, or other suitable materials to fill the space or gap between the device structure 16 and the second portion 18b, thereby effectively reducing the penetration of solution or gas into the release layer 14 during manufacturing processes. According to some embodiments, the toughness of the first portion 18a may be greater than that of the second portion 18b, but not limited thereto. In other embodiments, a visible light transmittance of the first portion 18a may be less than that of the second portion 18b, but not limited thereto.

In the embodiment of FIG. 8, a top view shape of the device structure 16 may be circular, and an opening OP of the second portion 18b may be rectangular, but not limited thereto. In some embodiments, the top view shape of the device structure 16 may be rectangular, and the opening OP of the second portion 18b may be circular.

FIG. 10 is a top view schematic diagram illustrating one of steps in a manufacturing method of an electronic device according to a seventh embodiment of the present disclosure. As shown in FIG. 10, the manufacturing method of this embodiment differs from the embodiment shown in FIG. 9 in that the barrier structure 18 may further include a third portion 18cextending from the first portion 18a along the upper surface and side surface of the second portion 18b to the side surface of the carrier 12. In this case, the third portion 18c may cover the side surface of the release layer 14, thereby reducing the risk of solution or gas penetrating into the release layer 14 during manufacturing processes. In the embodiment of FIG. 10, the first portion 18a and the third portion 18c may include the same or different materials.

In summary, in the manufacturing method of the electronic device of the present disclosure, before performing the surface treatment step, the exposed portion of the release layer may be shielded by the barrier structure, thereby reducing the degree of penetration into the release layer during the surface treatment step. This prevents a reduction in adhesion of the release layer and lowers the probability of the device structure delaminated from the carrier during subsequent processes.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A manufacturing method of an electronic device, comprising:
providing a carrier;
forming a release layer on the carrier;
providing a device structure on the release layer and exposing a portion of an upper surface of the release layer;
forming a barrier structure on the portion of the upper surface of the release layer; and
performing a surface treatment step on the device structure after forming the barrier structure.

2. The manufacturing method of the electronic device according to claim 1, wherein providing the device structure comprises:
providing at least one electronic unit on the release layer; and
forming a package layer on the at least one electronic unit, wherein the package layer surrounds the at least one electronic unit.

3. The manufacturing method of the electronic device according to claim 2, wherein the barrier structure is formed between providing the at least one electronic unit and forming the package layer.

4. The manufacturing method of the electronic device according to claim 1, wherein the barrier structure is formed before providing the device structure.

5. The manufacturing method of the electronic device according to claim 1, wherein the barrier structure is formed after providing the device structure.

6. The manufacturing method of the electronic device according to claim 1, wherein the barrier structure extends onto the carrier and covers a side surface of the release layer.

7. The manufacturing method of the electronic device according to claim 6, wherein the barrier structure further extends onto the device structure.

8. The manufacturing method of the electronic device according to claim 6, wherein the barrier structure extends onto a side surface of the carrier.

9. The manufacturing method of the electronic device according to claim 1, wherein the barrier structure comprises a first portion and a second portion, the first portion is disposed on the portion of the upper surface of the release layer and extends onto the carrier, and the second portion is disposed on the device structure.

10. The manufacturing method of the electronic device according to claim 9, wherein the second portion extends onto the first portion.

11. The manufacturing method of the electronic device according to claim 9, wherein the first portion comprises an insulating material, and the second portion comprises a conductive material.

12. The manufacturing method of the electronic device according to claim 1, wherein the barrier structure comprises a conductive material.

13. The manufacturing method of the electronic device according to claim 1, further comprising removing the barrier structure, the release layer, and the carrier after the surface treatment step.

14. The manufacturing method of the electronic device according to claim 13, wherein removing the barrier structure comprises irradiating the barrier structure with light, and removing the release layer comprises heating the release layer.

15. The manufacturing method of the electronic device according to claim 13, wherein removing the barrier structure comprises irradiating the barrier structure with first light, removing the release layer comprises irradiating the release layer with second light, and a wavelength range of the first light is not overlapped with a wavelength range of the second light.

16. The manufacturing method of the electronic device according to claim 1, wherein the device structure comprises a wafer.

17. An electronic device, comprising:
an electronic unit;
a package layer surrounding the electronic unit; and
a circuit structure disposed on the electronic unit and the package layer and electrically connected to the electronic unit, wherein the circuit structure comprises at least one pad, a side surface of the at least one pad has a recess in a cross-sectional view.

18. The electronic device according to claim 17, wherein an upper surface of the at least one pad has an uneven surface.

19. The electronic device according to claim 17, wherein the circuit structure comprises at least one conductive layer and at least one insulating layer, and the at least one conductive layer comprises the at least one pad, wherein the at least one insulating layer comprises at least one through hole, and the at least one pad is disposed in the at least one through hole.

20. The electronic device according to claim 19, wherein a depth of the at least one through hole is greater than a thickness of the at least one pad.
